(19) United States
(12) Patent Application Publication
(10) Pub. No.: US 2026/0223682 A1
(43) Pub. Date: Jul. 30, 2026

(54) SEMICONDUCTOR WAFERS WITH BURIED CONNECTORS AND ASSOCIATED SYSTEMS AND METHODS

(71) Applicant: Micron Technology, Inc., Boise, ID (US)

(72) Inventors: Kunal R. Parekh, Boise, ID (US); Kyle K. Kirby, Eagle, ID (US); Nancy Lomeli, Boise, ID (US); Michel Koopmans, Boise, ID (US)

(21) Appl. No.: 19/406,948

(22) Filed: Dec. 3, 2025

Related U.S. Application Data
(60) Provisional application No. 63/751,168, filed on Jan. 29, 2025.

(51) Int. Cl. H10W 42/00; H10W 20/20

(52) U.S. Cl. CPC H10W 42/121; H10W 20/20

(57) ABSTRACT

Semiconductor device assemblies including one or more semiconductor wafers with buried connectors and associated systems and methods are disclosed herein. In some embodiments, a semiconductor wafer includes one or more dielectric layers defining a frontside and a backside of the semiconductor wafer, integrated circuitry formed on or within the dielectric layers, and an array of connectors formed within the dielectric layers. The array of connectors can be arranged in a geometric pattern. Individual ones of the array of connectors can be oriented along a direction extending between the frontside and the backside of the semiconductor wafer. A first subset of the array of connectors can be exposed at least one of the frontside or the backside of the semiconductor wafer. A second subset of the array of connectors can be fully embedded in the one or more dielectric layers.

### CROSS-REFERENCE TO RELATED APPLICATIONS

The present application claims priority to U.S. Provisional Patent Application No. 63/751,168, filed January 29, 2025, the disclosure of which is incorporated herein by reference in its entirety.

### TECHNICAL FIELD

The present technology generally relates to semiconductor device assemblies, and more particularly relates to semiconductor wafers with buried connectors, and associated systems and methods.

### BACKGROUND

Microelectronic devices generally have a die (i.e., a chip) that includes integrated circuitry with a high density of very small components. Typically, dies include an array of very small bond pads electrically coupled to the integrated circuitry. The bond pads are external electrical contacts through which the supply voltage, signals, etc., are transmitted to and from the integrated circuitry. After dies are formed, they are “packaged” to couple the bond pads to a larger array of electrical terminals that can be more easily coupled to the various power supply lines, signal lines, and ground lines. Conventional processes for packaging dies include electrically coupling the bond pads on the dies to an array of leads, ball pads, or other types of electrical terminals, and encapsulating the dies to protect them from environmental factors (e.g., moisture, particulates, static electricity, and physical impact).

### BRIEF DESCRIPTION OF THE DRAWINGS

Features, aspects, and advantages of the presently disclosed technology may be better understood with regard to the following drawings.

FIG. 1 is a schematic side view of a semiconductor wafer configured in accordance with embodiments of the present technology.

FIGS. 2-5 are schematic top views of various semiconductor wafers configured in accordance with embodiments of the present technology.

FIG. 6 is a schematic side view of a semiconductor device assembly configured in accordance with embodiments of the present technology.

FIG. 7 illustrates interoperability and modularity of a semiconductor wafer configured in accordance with embodiments of the present technology.

FIG. 8 is a flowchart illustrating a method for packaging a semiconductor device assembly in accordance with embodiments of the present technology.

A person skilled in the relevant art will understand that the features shown in the drawings are for purposes of illustrations, and variations, including different and/or additional features and arrangements thereof, are possible.

### DETAILED DESCRIPTION

### I. Overview

Embodiments of the present technology are directed to semiconductor device assemblies including one or more semiconductor wafers with buried connectors, and associated systems and methods. Wafers typically include contact pads, bond pads, and/or the like for electrically coupling to other components in a semiconductor device assembly, such as another wafer stacked therewith. In many existing wafers, the number and arrangement of such contact pads, bond pads, and/or the like are tailored specific to the particular application. For example, if a first wafer is intended to be bonded to a second wafer, each of the first wafer and the second wafer may be manufactured to include contact pads in a compatible arrangement without any excess, unconnected contact pads. The tailored nature of the contact pads, bond pads, and/or the like, however, can unduly limit the usage of the wafers in other applications. For example, if the second wafer needs to be replaced with a third wafer, the first wafer may also need to be replaced due to, e.g., lack of contact pads, bond pads, and/or the like that are compatible with the third wafer. This can result in wasting the first wafer.

Embodiments of the present technology address at least some of the above described issues associated with limited compatibility. For example, embodiments of the present disclosure include semiconductor wafers that include an array of connectors, select ones of which may be accessed (e.g., exposed) depending on the application, thereby providing compatibility with multiple other wafers, semiconductor layers, and/or the like. Thus, in some embodiments, a semiconductor wafer can include (i) one or more dielectric layers defining a frontside of the semiconductor wafer and a backside of the semiconductor wafer opposite the frontside, (ii) integrated circuitry formed on or within the one or more dielectric layers, and (iii) an array of connectors formed within the one or more dielectric layers. The array of connectors can be arranged in a geometric pattern. Individual ones of the array of connectors can be oriented along a direction extending between the frontside and the backside of the semiconductor wafer. A first subset of the array of connectors can be exposed at least one of the frontside or the backside of the semiconductor wafer. A second subset of the array of connectors can be (e.g., can remain) fully embedded in the one or more dielectric layers.

In some embodiments, a semiconductor device assembly includes a semiconductor wafer and a semiconductor layer bonded thereto. The semiconductor wafer can include one or more dielectric layers defining a frontside of the semiconductor wafer and a backside of the semiconductor wafer opposite the frontside, integrated circuitry formed on or within the one or more dielectric layers, and an array of connectors formed within the one or more dielectric layers. The array of connectors can be arranged in a geometric pattern. Individual ones of the array of connectors can be oriented along a direction extending between the frontside and the backside of the semiconductor wafer. The array of connectors can include a first subset of connectors and a second subset of connectors. The semiconductor layer can be bonded to the frontside or the backside of the semiconductor wafer and have metal traces. The first subset of connectors can be electrically coupled to the metal traces of the semiconductor layer. The second subset of connectors can be (e.g., remain) fully embedded in the one or more dielectric layers.

In some embodiments, a method for packaging a semiconductor device assembly includes (i) providing a semiconductor wafer, (ii) bonding a semiconductor layer to the semiconductor wafer, and (iii) electrically coupling the semiconductor layer to the semiconductor wafer. The semiconductor wafer can include one or more dielectric layers defining a frontside of the semiconductor wafer and a backside of the semiconductor wafer opposite the frontside, integrated circuitry formed on or within the one or more dielectric layers, and an array of connectors formed within the one or more dielectric layers. The array of connectors can be arranged in a geometric pattern. Individual ones of the array of connectors can be oriented along a direction extending between the frontside and the backside of the semiconductor wafer. The array of connectors can include a first subset of connectors and a second subset of connectors. Bonding the semiconductor layer to the semiconductor wafer can include bonding the semiconductor layer to the frontside or the backside of the semiconductor wafer. The semiconductor layer can include metal traces. Electrically coupling the semiconductor layer to the semiconductor wafer can include electrically coupling the metal traces of the semiconductor layer to the first subset of connectors. The second subset of connectors can remain fully embedded in the one or more dielectric layers.

Embodiments of the present technology provide semiconductor wafers with compatibility with various other semiconductor layers (e.g., various other wafers). The array of connectors can include more connectors than needed for any given application, and select ones thereof can be selectively accessed depending on the application. Therefore, semiconductor wafers configured in accordance with embodiments of the present technology can be electrically coupled to various designs of semiconductor layers having, e.g., various numbers and/or arrangements of contact pads, bond pads, and/or the like. Due to this high modularity stemming from the semiconductor wafers’ interoperability with multiple different semiconductor layers, embodiments of the present technology reduce (i) the need for manufacturing highly tailored wafers and (ii) the risk of having to discard wafers for lack of compatibility, resulting in cost and time savings. Embodiments of the present technology can also have improved warpage resistance compared to many existing wafers, as the array of connectors can provide structural support to the semiconductor wafer.

In the Figures, identical reference numbers identify generally similar, and/or identical, elements. Many of the details, dimensions, and other features shown in the Figures are merely illustrative of particular embodiments of the disclosed technology. Accordingly, other embodiments can have other details, dimensions, and features without departing from the spirit or scope of the disclosure. In addition, those of ordinary skill in the art will appreciate that further embodiments of the various disclosed technologies can be practiced without several of the details described below.

### II. Select Embodiments of Semiconductor Wafers

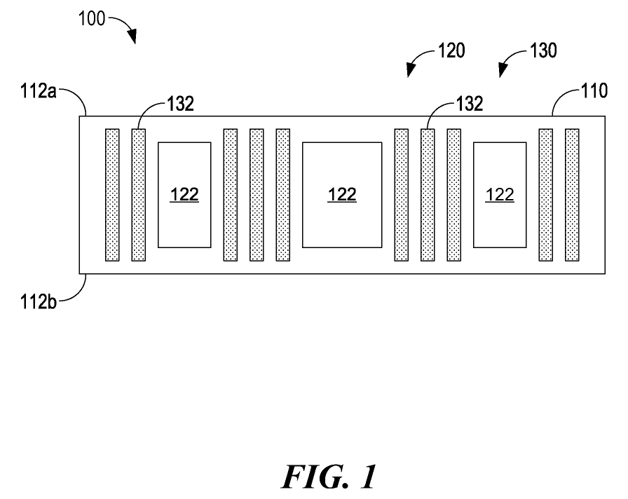

FIG. 1 is a schematic side view of a semiconductor wafer 100 configured in accordance with embodiments of the present technology. The semiconductor wafer 100 can include one or more dielectric layers 110, integrated circuitry 120, and an array of connectors 130. The one or more dielectric layers 110 can define a frontside 112a of the semiconductor wafer 100 and a backside 112b of the semiconductor wafer 100 opposite the frontside 112a. The one or more dielectric layers 110 are shown schematically as a single block for illustrative purposes only. The integrated circuitry 120 can be formed on or within the one or more dielectric layers 110, and can include one or more integrated circuits 122 (three illustrated in FIG. 1) spaced apart from one another. Each integrated circuit 122 can be associated with a die included in the semiconductor wafer 100, and therefore the one or more integrated circuits 122 may also be referred to herein as one or more dies 122.

The array of connectors 130 can be formed within the one or more dielectric layers 110 and can include a plurality of connectors 132. Individual ones of the connectors 132 can be elongate in shape and oriented along a direction extending between the frontside 112a and the backside 112b of the semiconductor wafer 100. As shown, the array of connectors 130 can be, at least initially, fully embedded in the one or more dielectric layers 110. As discussed in further detail herein, select ones of the connectors 132 can be selectively accessed to enable electrical connection to another semiconductor layer. The connectors 132 can be composed of copper, tungsten, polycrystalline silicon, and/or other suitable conductive material. In some embodiments, each of the connectors 132 also includes an insulating or barrier layer around the conductive material.

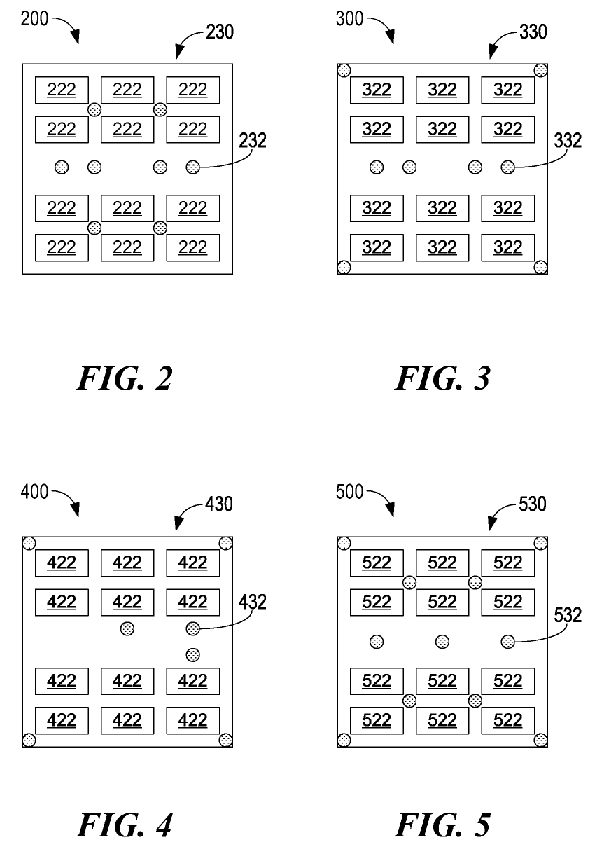

In the illustrated embodiment, the integrated circuits 122 are interspersed with the connectors 132 (or subgroups thereof) in a lateral direction (e.g., in a direction parallel to the frontside 112a of the semiconductor wafer 100) in the one or more dielectric layers 110. Also, as discussed in further detail below with reference to FIG. 2–5, the connectors 132 can be arranged in a geometric pattern. In some embodiments, the connectors 132 are designed to be arranged in a predetermined geometric pattern, and the integrated circuits 122 are designed to be arranged to accommodate (e.g., avoid) the connectors 132 arranged in the predetermined geometric pattern. For example, the connectors 132 can be arranged in a grid, and the layout of the integrated circuits 122 can be modified from an initial layout such that the integrated circuits 122 are arranged in gaps between adjacent ones of the connectors 132. In some embodiments, the integrated circuits 122 are arranged in a predetermined layout (e.g., without regard to the array of connectors 130), and the connectors 132 are arranged in any space left available by the predetermined layout. Additional details regarding the layout of the integrated circuits 122 and the geometric pattern of the connectors 132 are provided below with reference to FIG. 2–5.

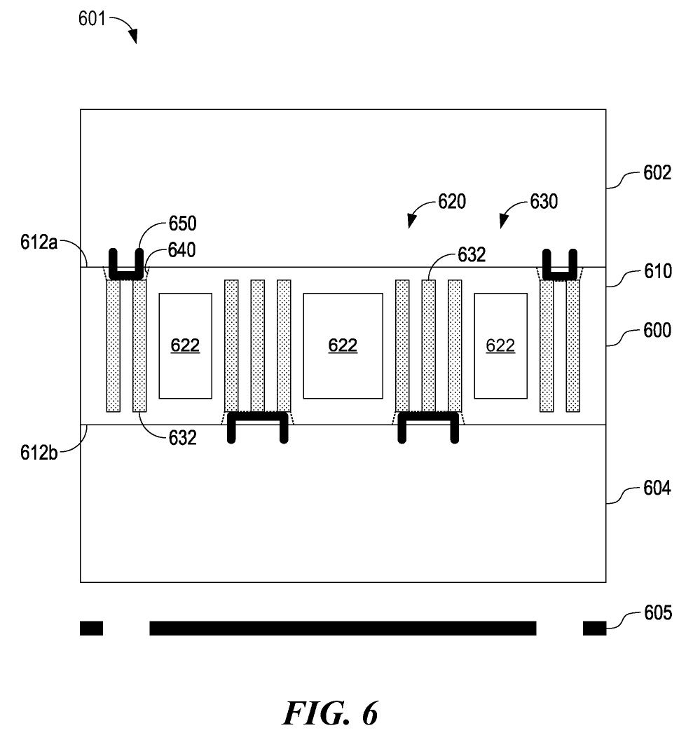

In some embodiments, the array of connectors 130 includes more connectors 132 than needed for any given application. In particular, the array of connectors 130 can be arranged in a geometric pattern that is a combination of multiple different arrangements of metal traces, contact pads, bond pads, and/or the like, where the multiple different arrangements may correspond to different semiconductor layers. Thus, once the specific application for the semiconductor wafer 100 is determined, select ones of the connectors 132 can be selectively accessed (e.g., from the frontside 112a and/or the backside 112b of the semiconductor wafer 100) such that a first subset of the connectors 132 is electrically coupled to another semiconductor layer and a second subset of the connectors is (e.g., remains) fully embedded in the one or more dielectric layers 110. Additional details regarding bonding the semiconductor wafer 100 with other semiconductor layers are provided below with reference to FIG. 6–8.

In some embodiments, the array of connectors 130 provides mechanical or structural support to the semiconductor wafer 100. For example, the one or more dielectric layers 110 can have a first rigidity and the connectors 132 can have a second rigidity greater than the first rigidity. Therefore, inclusion of the connectors 132 can increase the overall rigidity, warpage resistance, and/or other mechanical properties of the semiconductor wafer 100. In some embodiments, the array of connectors 130 is arranged in a manner that increases such mechanical properties more so than other arrangements. For example, evenly distributing the connectors 132 across the semiconductor wafer 100 may provide a higher warpage resistance than focusing the connectors 132 in one corner of the semiconductor wafer 100.

FIG. 2–5 are schematic top views of various semiconductor wafers 200, 300, 400, 500 configured in accordance with embodiments of the present technology. As described in further detail herein, the array of connectors included in each of the semiconductor wafers 200, 300, 400, 500 can be arranged in a geometric pattern. The term “geometric pattern,” as used herein, refers to a collection of objects in which the objects are arranged in an at least partially repetitive and orderly manner based on geometric principles, such as objects positioned in a grid formation, a rectangular formation, a circular formation, a triangular formation, a hexagonal formation, or a combination thereof. A geometric pattern may be either symmetrical or asymmetrical. However, a collection of objects in which the objects are in an arrangement that lacks such repetition and mathematical basis, such as a random scatter of objects, would not be considered a geometric pattern.

Referring first to FIG. 2, the semiconductor wafer 200 includes a plurality of dies or integrated circuits 222 and an array of connectors 230. In the illustrated embodiment, the plurality of integrated circuits 222 is arranged in two groups of 2 rows × 3 columns. The array of connectors 230 can include connectors 232 interspersed with the integrated circuits 222. More specifically, four connectors 232 are positioned at the spots surrounded by four integrated circuits 222 each, and four connectors 232 are positioned linearly along a row between the two groups of the integrated circuits 222. As shown, the connectors 232 are arranged in a geometric pattern such that the connectors 232 are aligned along rows and/or columns, the connectors 232 are symmetrical (e.g., about vertical and horizontal planes), and six connectors 232 form a hexagon centered with the semiconductor wafer 200.

Referring next to FIG. 3, the semiconductor wafer 300 includes a plurality of dies or integrated circuits 322 and an array of connectors 330. In the illustrated embodiment, the plurality of integrated circuits 322 is arranged in two groups of 2 rows × 3 columns. The array of connectors 330 can include connectors 332 interspersed with the integrated circuits 322. More specifically, four connectors 332 are positioned at the four corners of the semiconductor wafer 300, and four connectors 332 are positioned linearly along a row between the two groups of the integrated circuits 322. As shown, the connectors 332 are arranged in a geometric pattern such that the connectors 332 are aligned along rows and/or columns, the connectors 332 are symmetrical (e.g., about vertical and horizontal planes), and at least a subset of the connectors 332 is positioned around (e.g., the entirety of) the integrated circuits 322.

Referring next to FIG. 4, the semiconductor wafer 400 includes a plurality of dies or integrated circuits 422 and an array of connectors 430. In the illustrated embodiment, the plurality of integrated circuits 422 is arranged in two groups of 2 rows × 3 columns. The array of connectors 430 can include connectors 432 interspersed with the integrated circuits 422. More specifically, four connectors 432 are positioned at the four corners of the semiconductor wafer 400, and three connectors 432 are positioned between the two groups of the integrated circuits 422 in a L-shape. As shown, the connectors 432 are arranged in a geometric pattern such that the connectors 432 are aligned along rows and/or columns, the connectors 432 are asymmetrical, and at least a subset of the connectors 432 is positioned around (e.g., the entirety of) the integrated circuits 422.

Referring next to FIG. 5, the semiconductor wafer 500 includes a plurality of dies or integrated circuits 522 and an array of connectors 530. In the illustrated embodiment, the plurality of integrated circuits 522 is arranged in two groups of 2 rows × 3 columns. The array of connectors 530 can include connectors 532 interspersed with the integrated circuits 522. More specifically, four connectors 532 are positioned at the four corners of the semiconductor wafer 500, four connectors 532 are positioned at the spots surrounded by four integrated circuits 522 each, and three connectors 532 are positioned linearly along a row between the two groups of the integrated circuits 522. As shown, the connectors 532 are arranged in a geometric pattern such that the connectors 532 are aligned along rows and/or columns, the connectors 532 are symmetrical (e.g., about vertical and horizontal planes), at least a subset of the connectors 532 is positioned around (e.g., the entirety of) the integrated circuits 522, and six connectors 532 form a hexagon centered with the semiconductor wafer 500.

It is appreciated that the semiconductor wafers 200, 300, 400, 500 of FIGS. 2-5 are merely illustrative examples, and that in other embodiments, semiconductor wafers can include integrated circuits and/or arrays of connectors in different geometric patterns. For example, a semiconductor wafer can include a different number and/or arrangement of integrated circuits, and connectors can be arranged around and/or in between the integrated circuits accordingly. In any case, by arranging the connectors in a geometric pattern, the connectors can align with metal traces, contact pads, bond pads, and/or the like included in other semiconductor layers, which are often also arranged in a geometric pattern. Moreover, a given geometric pattern may accommodate multiple different arrangements of metal traces, contact pads, bond pads, and/or the like. For example, the geometric pattern of the array of connectors 530 illustrated in FIG. 5 can accommodate both (i) an arrangement in which metal traces are at the four corners of another wafer (e.g., having the same dimensions as the semiconductor wafer 500) and (ii) an arrangement in which metal traces are arranged in a hexagon centered with the other wafer. Accordingly, and as discussed in further detail herein, select ones of the connectors can be selectively accessed based at least in part on the arrangement provided in the other wafer (or other semiconductor layer).

In some embodiments, the geometric pattern of the array of connectors is selected based at least in part on achieving one or more particular goals. For example, the connectors can be arranged to minimize the lengths of metal traces needed to electrically couple two wafers, including the wafer housing the connectors. In another example, the connectors can be arranged to optimize the connectivity between the two wafers. In yet another example, the connectors can be arranged to maximize or at least improve the warpage resistance and/or other mechanical properties of the wafer.

### II. Select Embodiments of Semiconductor Device Assemblies

FIG. 6 is a schematic side view of a semiconductor device assembly 601 configured in accordance with embodiments of the present technology. The semiconductor device assembly 601 can include a semiconductor wafer 600, a first semiconductor layer 602 bonded to the semiconductor wafer 600, and a second semiconductor layer 604 bonded to the semiconductor wafer 600. It is appreciated that the semiconductor wafer 600 of FIG. 6 may be an example of the semiconductor wafer 100 of FIG. 1, and that similarly named and numbered elements described above are coupled and function similarly below.

The semiconductor wafer 600 can include one or more dielectric layers 610, integrated circuitry 620, and an array of connectors 630. The one or more dielectric layers 610 can define a frontside 612a of the semiconductor wafer 600 and a backside 612b of the semiconductor wafer 600 opposite the frontside 612a. The integrated circuitry 620 can be formed on or within the one or more dielectric layers 610, and can include one or more integrated circuits 622 (three illustrated in FIG. 6) spaced apart from one another. Each integrated circuit 622 can be associated with a die included in the semiconductor wafer 600, and therefore the one or more integrated circuits 622 may also be referred to herein as one or more dies 622. The array of connectors 630 can be formed within the one or more dielectric layers 610 and can include a plurality of connectors 632. Individual ones of the connectors 632 can be elongate in shape and oriented along a direction extending between the frontside 612a and the backside 612b of the semiconductor wafer 600. As shown, the array of connectors 630 can be, at least initially, fully embedded in the one or more dielectric layers 610.

The first semiconductor layer 602 can be bonded to the frontside 612a of the semiconductor wafer 600, and the second semiconductor layer 604 can be bonded to the backside 612b of the semiconductor wafer 600. The first semiconductor layer 602 and/or the second semiconductor layer 604 can be another semiconductor wafer (e.g., an array wafer, a CMOS wafer), a redistribution layer (RDL), a dedicated power delivery layer, and/or the like. Each of the first semiconductor layer 602 and the second semiconductor layer 604 can be bonded to the semiconductor wafer 600 via hybrid bonding and/or other suitable bonding technique.

Prior to bonding the first semiconductor layer 602 and the second semiconductor layer 604 to the semiconductor wafer 600, however, select ones of the connectors 632 can be accessed (e.g., tapped) from the frontside 612a or the backside 612b of the semiconductor wafer 600 by removing portions of the dielectric layers 610 thereat. For example, a masking layer 605 with a desired pattern can be applied to the frontside 612a or the backside 612b of the semiconductor wafer 600, and photolithography and etching (e.g., wet etching, dry etching) can be performed to remove portions of the dielectric layers 610 according to the desired pattern on the masking layer 605. Other suitable techniques can be used to remove portions of the dielectric layers 610. Thus, one or more openings 640 in the dielectric layers 610 can be formed to expose select ones of the connectors 632 at the frontside 612a or the backside 612b of the semiconductor wafer 600. As previously discussed herein, the determination of which connectors 632 to expose and from which side can be based at least in part on the specific application.

Once the openings 640 are formed in the dielectric layers 610, metal traces 650 and/or the like (e.g., power rails) can be extended into the openings 640 to make electrical contact with the corresponding connector(s) 632. The metal traces 650 (or other electrically conductive structures) can also be connected to the first semiconductor layer 602, the second semiconductor layer 604, and/or other components (e.g., an external power source) such that the semiconductor wafer 600 can be electrically coupled to those other layers or components. For example, in the illustrated embodiment, the connectors 632 towards the edges of the semiconductor wafer 600 are electrically coupled to the first semiconductor layer 602 via the metal traces 650 at the frontside 612a, and the connectors 632 towards the center of the semiconductor wafer 600 are electrically coupled to the second semiconductor layer 604 via the metal traces 650 at the backside 612b. In other embodiments, one or more of the connectors 632 may not be accessed (e.g., tapped) and can remain fully embedded in the dielectric layers 610. In some embodiments, the metal traces 650 and the connectors 632 are used for delivering power and/or signals to components of the semiconductor wafer 600, such as the integrated circuitry 620.

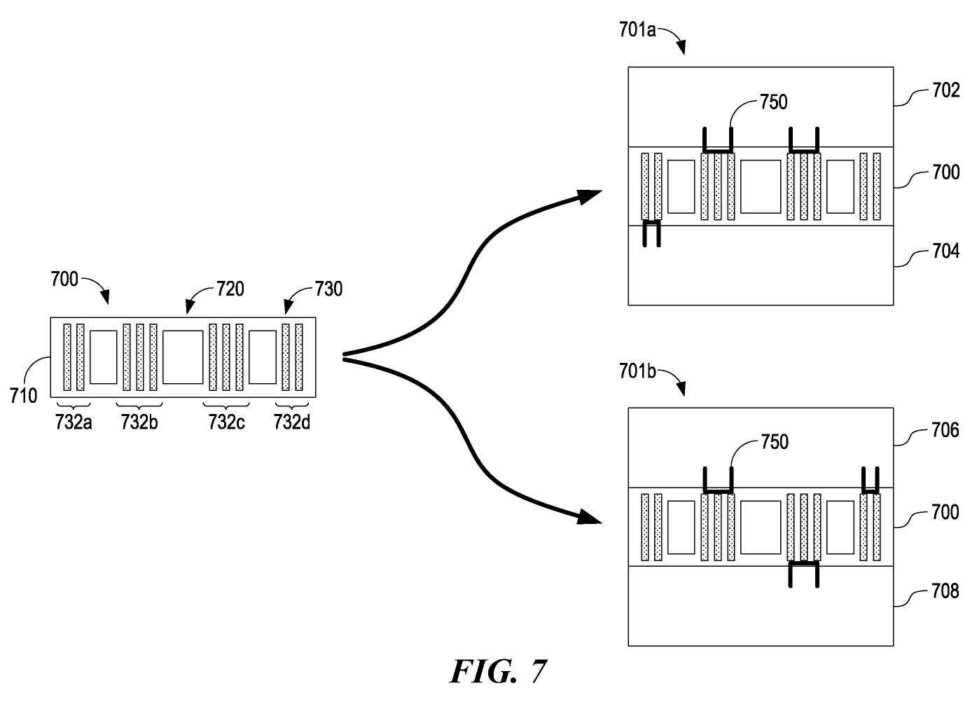

FIG. 7 illustrates interoperability and modularity of a semiconductor wafer 700 configured in accordance with embodiments of the present technology. It is appreciated that the semiconductor wafer 700 of FIG. 7 may be an example of the semiconductor wafer 100 of FIG. 1. For example, the semiconductor wafer 700 can include one or more dielectric layers 710, integrated circuitry 720, and an array of connectors 730. The array of connectors 730 can include a first group of connectors 732a, a second group of connectors 732b, a third group of connectors 732c, and a fourth group of connectors 732d (collectively referred to as “the connectors 732”).

As indicated by the two arrows extending rightward and away from the semiconductor wafer 700 on the left side of FIG. 7, the semiconductor wafer 700 can be assembled with different semiconductor layers depending on, e.g., the specific application. Referring first to the top-right corner of FIG. 7, the semiconductor wafer 700 can be assembled with a first semiconductor layer 702 bonded to a frontside of the semiconductor wafer 700 and a second semiconductor layer 704 bonded to a backside of the semiconductor wafer 700 to form a first semiconductor device assembly 701a. As shown, the semiconductor wafer 700 can be electrically coupled to the first semiconductor layer 702 via the second group of connectors 732b and the third group of connectors 732c (and corresponding metal traces 750), and electrically coupled to the second semiconductor layer 704 via the first group of connectors 732a (and corresponding metal traces 750). The fourth group of connectors 732d is not connected to either semiconductor layer. Therefore, a first subset of the array of connectors 730 (e.g., the second and third groups of connectors 732b, 732c) is electrically coupled to the first semiconductor layer 702, a second subset of the array of connectors 730 (e.g., the fourth group of connectors 732d) remains fully embedded in the one or more dielectric layers 710, and a third subset of the array of connectors 730 (e.g., the first group of connectors 732a) is electrically coupled to the second semiconductor layer 704.

Referring next to the bottom-right corner of FIG. 7, the semiconductor wafer 700 can be assembled with a third semiconductor layer 706 bonded to the frontside of the semiconductor wafer 700 and a fourth semiconductor layer 708 bonded to the backside of the semiconductor wafer 700 to form a second semiconductor device assembly 701b. As shown, the semiconductor wafer 700 can be electrically coupled to the third semiconductor layer 706 via the second group of connectors 732b and the fourth group of connectors 732d (and corresponding metal traces 750), and electrically coupled to the fourth semiconductor layer 708 via the third group of connectors 732c (and corresponding metal traces 750). The first group of connectors 732a is not connected to either semiconductor layer. Therefore, a first subset of the array of connectors 730 (e.g., the second and fourth groups of connectors 732b, 732d) is electrically coupled to the third semiconductor layer 706, a second subset of the array of connectors 730 (e.g., the first group of connectors 732a) remains fully embedded in the one or more dielectric layers 710, and a third subset of the array of connectors 730 (e.g., the third group of connectors 732c) is electrically coupled to the fourth semiconductor layer 708.

Notably, in each of the first semiconductor device assembly 701a and the second semiconductor device assembly 701b, the semiconductor wafer 700 includes more connectors 732 than needed. Accordingly, one or more of the connectors 732 can remain fully embedded in the dielectric layers 710 and not electrically coupled to other semiconductor layers.

Evident from the first and second semiconductor device assemblies 701a, 701b, the array of connectors 730 can include a sufficient number of connectors 732 and in a geometric pattern so as to be compatible with (e.g., be electrically coupled to) the first semiconductor layer 702, the second semiconductor layer 704, the third semiconductor layer 706, and/or the fourth semiconductor layer 708. It is appreciated that the first and second semiconductor device assemblies 701a, 701b are merely illustrative examples, and that the semiconductor wafer 700 can be bonded to other semiconductor layers and/or in different arrangements to form different semiconductor device assemblies. Accordingly, the same semiconductor wafer 700 can be assembled with different semiconductor layers and electrically coupled thereto without the need to, e.g., modify and adapt the semiconductor wafer 700.

### IV. Select Embodiments of Methods for Manufacturing Hybrid Semiconductor Devices

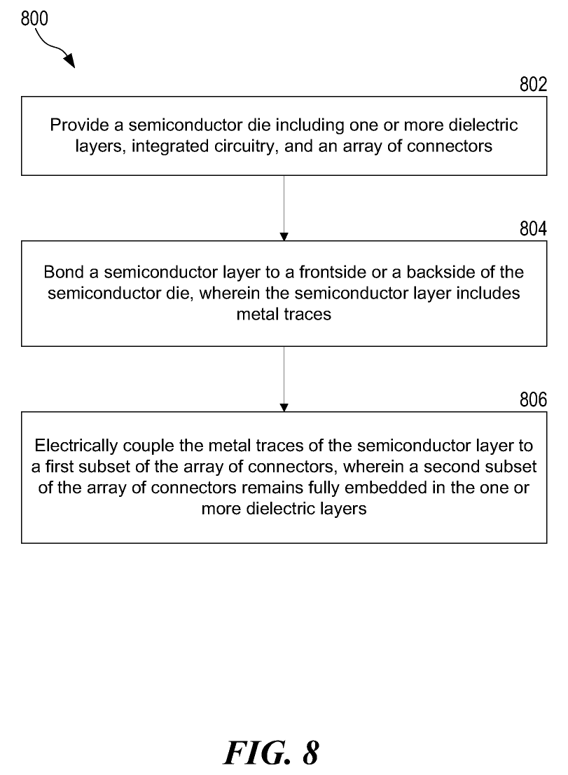

FIG. 8 is a flowchart illustrating a method 800 for packaging a semiconductor device assembly in accordance with embodiments of the present technology. While the steps of the method 800 are described below in a particular order, one or more of the steps can be performed in a different order or omitted, and the method 800 can include additional and/or alternative steps. Additionally, although the method 800 may be described below with reference to the embodiments of the present technology described herein, the method 800 can be performed with other embodiments of the present technology.

The method 800 begins at block 802 by providing a semiconductor wafer including one or more dielectric layers, integrated circuitry, and an array of connectors. The one or more dielectric layers can define a frontside of the semiconductor wafer and a backside of the semiconductor opposite the frontside. The integrated circuitry can be formed on or within the one or more dielectric layers. The array of connectors can be formed within the one or more dielectric layers and can be arranged in a geometric pattern. Individual ones of the array of connectors can be oriented along a direction extending between the frontside and the backside of the semiconductor wafer. The array of connectors can include first and second subsets of connectors.

At block 804, the method 800 continues by bonding a semiconductor layer to the frontside or the backside of the semiconductor wafer. The semiconductor layer can include metal traces. In some embodiments, prior to bonding the semiconductor layer to the semiconductor wafer, the first subset of connectors at the frontside or the backside can be exposed by removing portions of the one or more dielectric layers thereat. For example, the method 800 can further include selectively exposing, using a masking layer, the first subset of connectors at the frontside or the backside of the semiconductor wafer.

At block 806, the method 800 continues by electrically coupling the metal traces of the semiconductor layer to the first subset of connectors. The second subset of connectors can remain fully embedded in the one or more dielectric layers.

In some embodiments, the array of connectors further includes a third subset of connectors, and the method 800 further continues by (i) bonding a second semiconductor layer to the other of the frontside or the backside of the semiconductor wafer, where the second semiconductor layer includes metal traces, and (ii) electrically coupling the metal traces of the second semiconductor layer to the third subset of connectors. The third subset of connectors may first be exposed at the other of the frontside or the backside of the semiconductor wafer for easier access (e.g., by using a masking layer to remove portions of the one or more dielectric layers thereat).

In some embodiments, the method 800 further continues by delivering power to the semiconductor wafer via the metal traces of the semiconductor layer and the first subset of connectors of the semiconductor wafer. For example, the semiconductor layer can be a dedicated power delivery layer.

### IV. Conclusion

It will be apparent to those having skill in the art that changes may be made to the details of the above-described embodiments without departing from the underlying principles of the present disclosure. In some cases, well known structures and functions have not been shown or described in detail to avoid unnecessarily obscuring the description of the embodiments of the present technology. Although steps of methods may be presented herein in a particular order, alternative embodiments may perform the steps in a different order. Similarly, certain aspects of the present technology disclosed in the context of particular embodiments can be combined or eliminated in other embodiments. Furthermore, while advantages associated with certain embodiments of the present technology may have been disclosed in the context of those embodiments, other embodiments can also exhibit such advantages, and not all embodiments need necessarily exhibit such advantages or other advantages disclosed herein to fall within the scope of the technology. Accordingly, the disclosure and associated technology can encompass other embodiments not expressly shown or described herein, and the invention is not limited except as by the appended claims.

Where the context permits, singular or plural terms may also include the plural or singular term, respectively. For example, throughout this disclosure, the singular terms “a,” “an,” and “the” include plural referents unless the context clearly indicates otherwise. Moreover, unless the word “or” is expressly limited to mean only a single item exclusive from the other items in reference to a list of two or more items, then the use of “or” in such a list is to be interpreted as including (a) any single item in the list, (b) all of the items in the list, or (c) any combination of the items in the list. Furthermore, as used herein, the phrase “and/or” as in “A and/or B” refers to A alone, B alone, and both A and B. Additionally, the terms “comprising,” “including,” “having,” and “with” are used throughout to mean including at least the recited feature(s) such that any greater number of the same features and/or additional types of other features are not precluded. Moreover, as used herein, the phrases “based on,” “depends on,” “as a result of,” and “in response to” shall not be construed as a reference to a closed set of conditions. For example, a step that is described as “based on condition A” may be based on both condition A and condition B without departing from the scope of the present disclosure. In other words, as used herein, the phrase “based on” shall be construed in the same manner as the phrase “based at least in part on” or the phrase “based at least partially on.”

Reference herein to “one embodiment,” “an embodiment,” “some embodiments” or similar formulations means that a particular feature, structure, operation, or characteristic described in connection with the embodiment can be included in at least one embodiment of the present technology. Thus, the appearances of such phrases or formulations herein are not necessarily all referring to the same embodiment. Furthermore, various particular features, structures, operations, or characteristics may be combined in any suitable manner in one or more embodiments.

Unless otherwise indicated, all numbers expressing numerical values used in the specification and claims, are to be understood as being modified in all instances by the term “about.” Accordingly, unless indicated to the contrary, the numerical parameters set forth in the specification and attached claims are approximations that may vary depending upon the desired properties sought to be obtained by the present technology. At the very least, and not as an attempt to limit the application of the doctrine of equivalents to the scope of the claims, each numerical parameter should at least be construed in light of the number of reported significant digits and by applying ordinary rounding techniques. The terms “about” and/or “substantially” as used herein shall be interpreted to mean within ±10% of the stated value. Additionally, all ranges disclosed herein are to be understood to encompass the endpoints, and any and all subranges subsumed therein. For example, a range of “1 to 10” includes any and all subranges between (and including) the minimum value of 1 and the maximum value of 10 (e.g., any and all subranges having a minimum value of equal to or greater than 1 and a maximum value of equal to or less than 10, such as 5.5 to 10).

The disclosure set forth above is not to be interpreted as reflecting an intention that any claim or example requires more features than those expressly recited in that claim or example. Rather, as the preceding examples and the following claims reflect, inventive aspects lie in a combination of fewer than all features of any single foregoing disclosed embodiment. Thus, the preceding examples and the following claims are hereby expressly incorporated into the Detailed Description, with each claim standing on its own as a separate embodiment. This disclosure includes all permutations of the independent claims with their dependent claims.

What is claimed is:

1. A semiconductor wafer, comprising:
one or more dielectric layers defining a frontside of the semiconductor wafer and a backside of the semiconductor wafer opposite the frontside;
integrated circuitry formed on or within the one or more dielectric layers; and
an array of connectors formed within the one or more dielectric layers, wherein the array of connectors is arranged in a geometric pattern, wherein individual ones of the array of connectors are oriented along a direction extending between the frontside and the backside of the semiconductor wafer,
wherein a first subset of the array of connectors is exposed at least one of the frontside or the backside of the semiconductor wafer, and
wherein a second subset of the array of connectors is fully embedded in the one or more dielectric layers.

2. The semiconductor wafer of claim 1, wherein each connector of the first subset of the array of connectors is exposed at only one of the frontside or the backside of the semiconductor wafer.

3. The semiconductor wafer of claim 1, wherein connectors of a first portion of the first subset of the array of connectors is exposed at the frontside of the semiconductor wafer, and wherein connectors of a second portion of the first subset of the array of connectors is exposed at the backside of the semiconductor wafer.

4. The semiconductor wafer of claim 1, wherein each connector of the first subset of the array of connectors is electrically coupled to a metal trace providing power.

5. The semiconductor wafer of claim 1, wherein the one or more dielectric layers have a first rigidity, wherein individual ones of the array of connectors have a second rigidity greater than the first rigidity, and wherein the array of connectors is configured to increase a warpage resistance of the semiconductor wafer.

6. The semiconductor wafer of claim 1, wherein the array of connectors is arranged in a symmetrical arrangement.

7. The semiconductor wafer of claim 1, wherein the array of connectors is arranged in an asymmetrical arrangement.

8. The semiconductor wafer of claim 1, wherein the array of connectors is arranged in rows and columns.

9. The semiconductor wafer of claim 1, wherein the integrated circuitry includes a plurality of integrated circuits spaced apart from one another, and wherein select ones of the array of connectors are positioned between adjacent ones of the plurality of integrated circuits.

10. The semiconductor wafer of claim 1, wherein select ones of the array of connectors are positioned around the integrated circuitry.

11. A semiconductor device assembly, comprising:
a semiconductor wafer including:
one or more dielectric layers defining a frontside of the semiconductor wafer and a backside of the semiconductor wafer opposite the frontside,
integrated circuitry formed on or within the one or more dielectric layers, and
an array of connectors formed within the one or more dielectric layers, wherein the array of connectors is arranged in a geometric pattern, wherein individual ones of the array of connectors are oriented along a direction extending between the frontside and the backside of the semiconductor wafer, and wherein the array of connectors includes a first subset of connectors and a second subset of connectors; and
a semiconductor layer bonded to the frontside or the backside of the semiconductor wafer and having metal traces,
wherein the first subset of connectors is electrically coupled to the metal traces of the semiconductor layer, and
wherein the second subset of connectors is fully embedded in the one or more dielectric layers.

12. The semiconductor device assembly of claim 11, wherein the semiconductor layer is a second semiconductor wafer including second integrated circuitry.

13. The semiconductor device assembly of claim 11, wherein the semiconductor layer is a redistribution layer (RDL) or a dedicated power delivery layer.

14. The semiconductor device assembly of claim 11, wherein the array of connectors further includes a third subset of connectors, wherein the semiconductor layer is a first semiconductor layer bonded to the frontside of the semiconductor wafer, wherein the semiconductor device assembly further comprises a second semiconductor layer bonded to the backside of the semiconductor wafer and having metal traces, and wherein the third subset of connectors is electrically coupled to the metal traces of the second semiconductor layer.

15. The semiconductor device assembly of claim 11, wherein the array of connectors is arranged to minimize lengths of the metal traces of the semiconductor layer electrically coupled to the first subset of connectors.

16. The semiconductor device assembly of claim 11, wherein the array of connectors is arranged to optimize connectivity between the semiconductor layer and the semiconductor wafer.

17. A method for packaging a semiconductor device assembly, the method comprising:
providing a semiconductor wafer including:
one or more dielectric layers defining a frontside of the semiconductor wafer and a backside of the semiconductor wafer opposite the frontside,
integrated circuitry formed on or within the one or more dielectric layers, and
an array of connectors formed within the one or more dielectric layers, wherein the array of connectors is arranged in a geometric pattern, wherein individual ones of the array of connectors are oriented along a direction extending between the frontside and the backside of the semiconductor wafer, and wherein the array of connectors includes a first subset of connectors and a second subset of connectors;
bonding a semiconductor layer to the frontside or the backside of the semiconductor wafer, wherein the semiconductor layer includes metal traces; and
electrically coupling the metal traces of the semiconductor layer to the first subset of connectors, wherein the second subset of connectors remain fully embedded in the one or more dielectric layers.

18. The method of claim 17, further comprising selectively exposing, using a masking layer, the first subset of connectors at the frontside or the backside of the semiconductor wafer.

19. The method of claim 17, wherein the array of connectors further includes a third subset of connectors, wherein bonding the semiconductor layer comprises bonding a first semiconductor layer to the frontside of the semiconductor wafer, and wherein the method further comprises:
bonding a second semiconductor layer to the backside of the semiconductor wafer, wherein the semiconductor layer includes metal traces; and
electrically coupling the metal traces of the second semiconductor layer to the third subset of connectors.

20. The method of claim 17, further comprising delivering power to the semiconductor wafer via the metal traces of the semiconductor layer and the first subset of connectors of the semiconductor wafer.
